(19) United States
(12) Patent Application Publication
(10) Pub. No.: US 2013/0139875 A1
(43) Pub. Date: Jun. 6, 2013

(54) THIN-FILM SOLAR CELL AND METHOD FOR FORMING THE SAME

(71) Applicants: Chia-Ling LEE, Tainan City (TW); Chien-Chung BI, Taichung City (TW)

(72) Inventors: Chia-Ling LEE, Tainan City (TW); Chien-Chung BI, Taichung City (TW)

(21) Appl. No.: 13/405,728

(22) Filed: Feb. 27, 2012

(30) Foreign Application Priority Data
Dec. 6, 2011 (TW) 100144946

(51) Int. Cl. H01L 31/076; H01L 31/20

(52) U.S. Cl. 136/255; 438/96; 257/E31.041

(57) ABSTRACT

The present invention discloses a thin-film solar cell and a method for forming the same. The thin-film solar cell includes a substrate and a semiconductor layer containing a P-type crystalline silicon layer over the substrate, a first I-type crystalline silicon layer on the P-type crystalline silicon layer, a first N-type crystalline silicon layer on the first I-type crystalline silicon layer, a second I-type crystalline silicon layer on the first N-type crystalline silicon layer and a second N-type crystalline silicon layer on the second I-type crystalline silicon layer. Wherein, the semiconductor layer is formed with additional I-type and N-type crystalline silicon layers, thereby enhancing the photoelectric conversion efficiency of the thin-film solar cell.

### CROSS-REFERENCE TO RELATED APPLICATION

This application claims the benefit of Taiwan Patent Application No. 100144946, filed on Dec. 6, 2011, in the Taiwan Intellectual Property Office, the disclosure of which is incorporated herein in its entirety by reference.

### BACKGROUND OF THE DISCLOSURE

1. Field of the Invention

The present invention relates to a thin-film solar cell and method for forming the same, and more particularly to a thin-film solar cell formed with additional I-type and N-type crystalline silicon layers on a three-layered P-I-N semiconductor layer of prior art and thereby having an improved photoelectric conversion efficiency, and a method for forming the same.

2. Brief Description of the Related Art

With the rise of environmental consciousness and the gradual depletion of other energies, solar energy has received more attention. Sun is an inexhaustible natural energy without any concern of shortage and monopoly. Since solar cells have the advantages of convenience, pollution-free and a long lifespan, it can be used as an energy source.

The commonly used solar cells may include thin-film solar cells, which have the advantages of lower cost, thinner, less electrical power loss, etc. According to the current technology, a common thin-film solar cell 1 of prior art is formed primarily on a three-layered P-I-N semiconductor layer 12 containing a P-type layer 121, I-type layer 122 and N-type layer 123 subsequently sputtered or chemical vapor deposited on a substrate 11 made of glass or metal, as shown in FIG. 1.

Although the development of thin-film solar cells has become mature gradually, there is still much to be improved. Take the above-mentioned thin-film solar cell structure of prior art for example, the semiconductor layer composing only a three-layered structure of P-type, I-type and N-type layer has a poor photoelectric conversion efficiency. Therefore, the solar cell has to be further improved in order to enhance the photoelectric conversion efficiency.

### SUMMARY OF THE DISCLOSURE

In order to solve the above-mentioned problems of prior art, the present invention is aimed to develop a thin-film solar cell and a method of forming the same, thereby solving the problem of poor photoelectric conversion efficiency. The crystalline silicon ingot is formed with a reduction of an increasing rate of defects, and thus the crystalline silicon ingot has a better crystal quality. Also, subsequently-formed solar batteries have higher photoelectric conversion efficiency.

The present invention proposes a thin-film solar cell including a substrate and a semiconductor layer containing a P-type crystalline silicon layer over the substrate, a first I-type crystalline silicon layer on the P-type crystalline silicon layer, a first N-type crystalline silicon layer on the first I-type crystalline silicon layer, a second I-type crystalline silicon layer on the first N-type crystalline silicon layer and a second N-type crystalline silicon layer on the second I-type crystalline silicon layer. The second I-type crystalline silicon layer has a thickness less than or equal to 20% of a thickness of the first I-type crystalline silicon layer.

In one embodiment, the substrate can be made of glass.

In one embodiment, the solar cell of the invention further includes an amorphous silicon layer between the substrate and the P-type crystalline silicon layer.

In one embodiment, the solar cell of the invention further includes a zinc oxide film layer on the second N-type crystalline silicon layer.

In one embodiment, the solar cell of the invention further includes an electrode layer on the zinc oxide film layer. The electrode layer can be made of a conductive metal.

In one embodiment, materials of the first and second I-type crystalline silicon layers and the first and second N-type crystalline silicon layers may contain an amorphous silicon and a micro-crystalline silicon.

In one embodiment, a total thickness of the first and second N-type crystalline silicon layers may be less than or equal to 10% of the thickness of the first I-type crystalline silicon layer.

In one embodiment, a total thickness of the first and second N-type crystalline silicon layers may be less than or equal to 200 Å.

The present invention proposes another thin-film solar cell including a substrate and a semiconductor layer containing a P-type crystalline silicon layer over the substrate, a first I-type crystalline silicon layer on the P-type crystalline silicon layer, a first N-type crystalline silicon layer on the first I-type crystalline silicon layer, a second I-type crystalline silicon layer on the first N-type crystalline silicon layer and a second N-type crystalline silicon layer on the second I-type crystalline silicon layer. The first I-type crystalline silicon layer has a thickness less than or equal to 20% of a thickness of the second I-type crystalline silicon layer.

In one embodiment, the total thickness of the first and second N-type crystalline silicon layers may be less than or equal to 10% of the thickness of the second I-type crystalline silicon layer.

The present invention further proposes a method for forming a thin-film solar cell including the following steps of providing a substrate, forming a P-type crystalline silicon layer over the substrate, forming a first I-type crystalline silicon layer on the P-type crystalline silicon layer, forming a first N-type crystalline silicon layer on the first I-type crystalline silicon layer, forming a second I-type crystalline silicon layer on the first N-type crystalline silicon layer, and forming a second N-type crystalline silicon layer on the second I-type crystalline silicon layer.

In one embodiment, the second I-type crystalline silicon layer may have a thickness less than or equal to 20% of a thickness of the first I-type crystalline silicon layer.

In one embodiment, the first I-type crystalline silicon layer may have a thickness less than or equal to 20% of a thickness of the second I-type crystalline silicon layer

In one embodiment, a total thickness of the first and second N-type crystalline silicon layers may be less than or equal to 10% of a thickness of the first I-type crystalline silicon layer.

In one embodiment, a total thickness of the first and second N-type crystalline silicon layers may be less than or equal to 10% of a thickness of the second I-type crystalline silicon layer.

The present invention proposes a thin-film solar cell including a substrate and a semiconductor layer containing a P-type crystalline silicon layer over the substrate, a first I-type crystalline silicon layer on the P-type crystalline silicon layer, a first N-type crystalline silicon layer on the first I-type crystalline silicon layer, a plurality of second I-type crystalline silicon layers having a bottommost one on the first N-type crystalline silicon layer, and a plurality of second N-type crystalline silicon layers interdigitally arranged with the second I-type crystalline silicon layers. A total thickness of the second I-type crystalline silicon layers can be less than or equal to 20% of a thickness of the first I-type crystalline silicon layer.

In one embodiment, a total thickness of the first N-type crystalline silicon layer and the second N-type crystalline silicon layers may be less than or equal to 10% of the thickness of the first I-type crystalline silicon layer.

The present invention proposes a thin-film solar cell including a substrate and a semiconductor layer containing a P-type crystalline silicon layer over the substrate, a plurality of first I-type crystalline silicon layers having a bottommost one on the P-type crystalline silicon layer, a plurality of first N-type crystalline silicon layers interdigitally arranged with the first I-type crystalline silicon layers, a second I-type crystalline silicon layer on the topmost one of the first N-type crystalline silicon layers, and a second N-type crystalline silicon layer on the second I-type crystalline silicon layer. A total thickness of the first I-type crystalline silicon layers can be less than or equal to 20% of a thickness of the second I-type crystalline silicon layer.

In one embodiment, a total thickness of the first N-type crystalline silicon layers and the second N-type crystalline silicon layer may be less than or equal to 10% of the thickness of the second I-type crystalline silicon layer.

Accordingly, with regards to the thin-film solar cell and the method for forming the same disclosed in the present invention, one or more second I-type crystalline silicon layers and one or more second N-type crystalline silicon layers are added into a semiconductor layer of the thin-film solar cell, and thus the three-layered P-I-N structure of the thin-film solar cell of prior art is modified. Besides, a total thickness of the semiconductor layer of the present invention containing additional layers can be equal to that of the semiconductor layer of prior art, but photoelectric conversion efficiency can be significantly enhanced.

The accompanying drawings are included to provide a further understanding of the invention, and are incorporated as a part of this specification. The drawings illustrate embodiments of the invention and, together with the description, serve to explain the principles of the invention.

### BRIEF DESCRIPTION OF THE DRAWINGS

FIG. 1 is a schematic view of a thin-film solar cell of prior art.

FIG. 2 is a schematic view of a thin-film solar cell in accordance with the first embodiment of the present invention.

FIG. 3 is a data map comparing the open circuit voltages of thin-film solar cells of prior art and the present invention.

FIG. 4 is a data map comparing the variation of bottom currents of thin-film solar cells of prior art and the present invention.

FIG. 5 is a curve diagram comparing the external quantum efficiencies (E.Q.E.) of thin-film solar cells of prior art and the present invention.

FIG. 6 is a data map comparing the variation of bottom currents of thin-film solar cells of the present invention, prior art and various compositions of semiconductor layers.

FIG. 7 is a schematic view of a thin-film solar cell in accordance with the second embodiment of the present invention.

FIG. 8 is a schematic view of a thin-film solar cell in accordance with the third embodiment of the present invention.

FIG. 9 is a schematic view of a thin-film solar cell in accordance with the fourth embodiment of the present invention.

FIG. 10 is a flow chart for forming a thin-film solar cell in accordance with an embodiment of the present invention.

### DETAILED DESCRIPTION OF THE PREFERRED EMBODIMENTS

Illustrative embodiments accompanying with figures are now described below to lead the characteristics, contents, advantages and effects of the invention to be understood by the Examiner. The illustrated figures serve only for explanation and should not be interpreted in a restrictive manner, and thus the scope of the invention should not be limited by the scale and arrangement illustrated in the figures.

The embodiment of the method for forming the thin-film solar cell of the present invention will be described below in light of the accompanying figures. In the following embodiments, like reference numbers indicate identical elements.

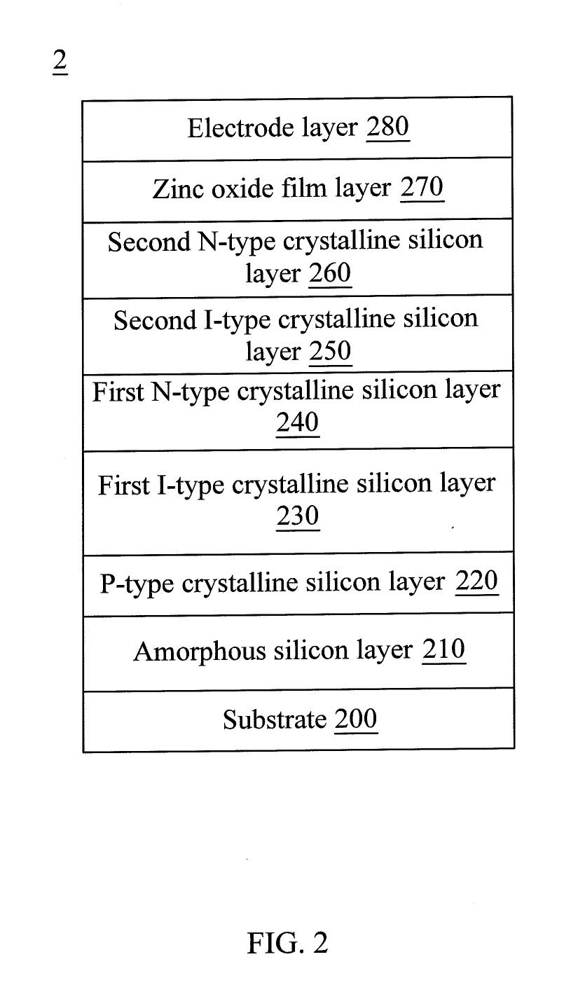

FIG. 2 is a schematic view of a thin-film solar cell in accordance with the first embodiment of the present invention. Referring to FIG. 2, a thin-film solar cell 2 may include a substrate 200, an amorphous silicon layer 210 on the substrate 200, a P-type crystalline silicon layer 220 on the amorphous silicon layer 210, a first I-type crystalline silicon layer 230 on the P-type crystalline silicon layer 220, a first N-type crystalline silicon layer 240 on the first I-type crystalline silicon layer 230, a second I-type crystalline silicon layer 250 on the first N-type crystalline silicon layer 240, a second N-type crystalline silicon layer 260 on the second I-type crystalline silicon layer 250, a zinc oxide film layer 270 on the second N-type crystalline silicon layer 260 and an electrode layer 280 on the zinc oxide film layer 270. The substrate 200 can be made of glass or other transparent materials. The amorphous silicon layer 210 acts as a light absorption layer which forms a photoelectric effect and creates a photocurrent. The material of the first I-type crystalline silicon layer 230, the first N-type crystalline silicon layer 240, the second I-type crystalline silicon layer 250 and the second N-type crystalline silicon layer 260 may contain an amorphous silicon and a micro-crystalline silicon. The zinc oxide film layer 270 can be made of a transparent conductive film or a zinc oxide doped with boron. The electrode layer 280 can be made of a transparent conductive film, a tin dioxide doped with fluorine, a zinc oxide doped with boron or a conductive metal. Preferably, the second I-type crystalline silicon layer 250 may have a thickness less than or equal to 20% of the thickness of the first I-type crystalline silicon layer 230. Preferably, the total thickness of the first and second N-type crystalline silicon layers 240 and 260 can be less than or equal to 10% of the thickness of the first I-type crystalline silicon layer 230 or less than or equal to 200 Å. However, the above-mentioned thicknesses and ratios are only an embodiment and should not be considered as a limitation of the invention.

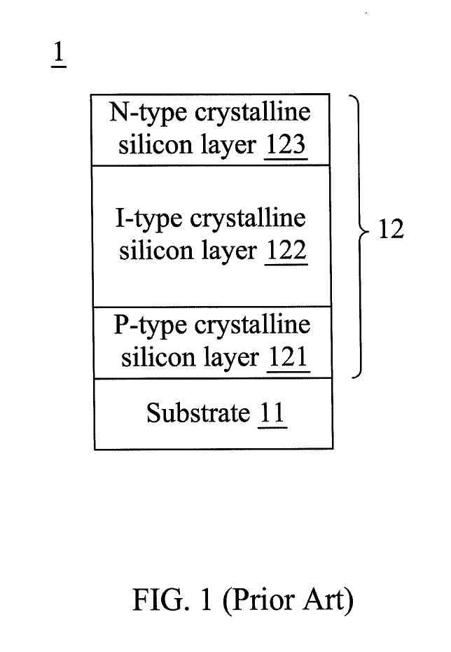

The difference between the thin-film solar cell 2 of the first embodiment and the thin-film solar cell 1 of prior art shown in FIG. 1 is that the additional I-type and N-type crystalline silicon layers, that is the second I-type and N-type crystalline silicon layers 250 and 260, are added into the three-layered P-I-N semiconductor layer 12 of prior art. The thickness of the semiconductor layer added with the second I-type and N-type crystalline silicon layers 250 and 260 can be equal to that of the semiconductor layer 12 of the thin-film solar cell 1. Accordingly, the thin-film solar cell 2 of the present invention can improve photoelectric conversion efficiency without changing the thickness of the semiconductor layer 12.

Generally, photoelectric conversion efficiency (EFF) is measured based on three values: a fill factors (FF), an open circuit voltage (V_{oc}) and a short-circuit current density (J_{sc}).

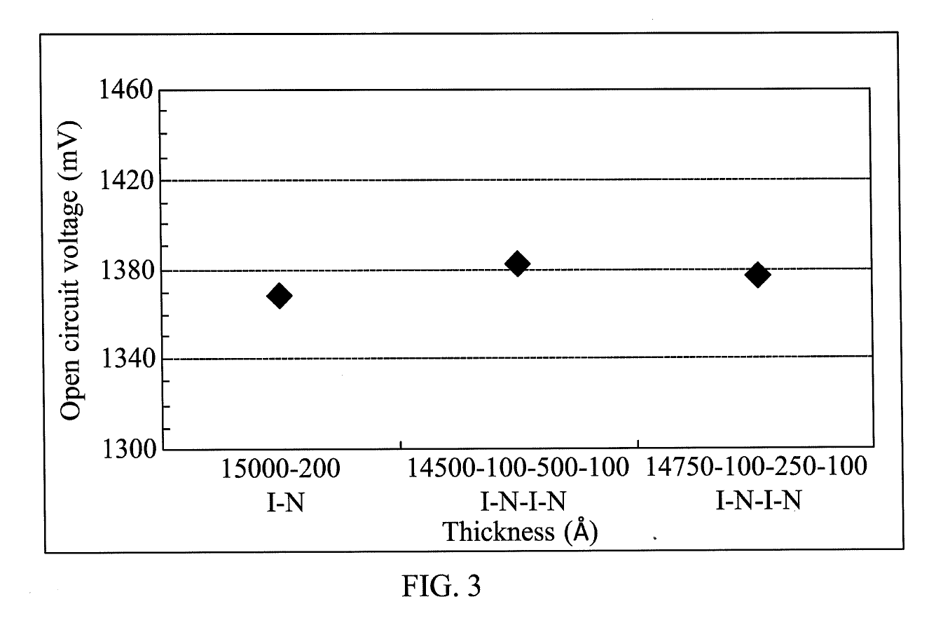

These three values are positively correlated to the photoelectric conversion efficiency. As evidenced in FIGS. 3-6, from the comparison between the thin-film solar cell 1 of prior art and the thin-film solar cell 2 of the present invention, the thin-film solar cell 2 of the present invention has a higher photoelectric conversion efficiency than that of the thin-film solar cell 1 of prior art.

FIG. 3 is a data map comparing the open circuit voltages of thin-film solar cells of prior art and the present invention. Referring to FIG. 3, the three-layered P-I-N semiconductor layer 12 of prior art (FIG. 1) and the PININ crystalline silicon layer (semiconductor layer) of the present invention have steady open circuit voltages. In the present invention, no matter how thick the second I-type crystalline silicon layer is, the semiconductor layer of the present invention maintains steady open circuit voltages. It is noted that a total thickness of the first and second I-type crystalline silicon layers 230 and 250 and first and second N-type crystalline silicon layers 240 and 260 of the present invention can be equal to that of the I-type crystalline silicon layer 122 and N-type crystalline silicon layer 123 of prior art.

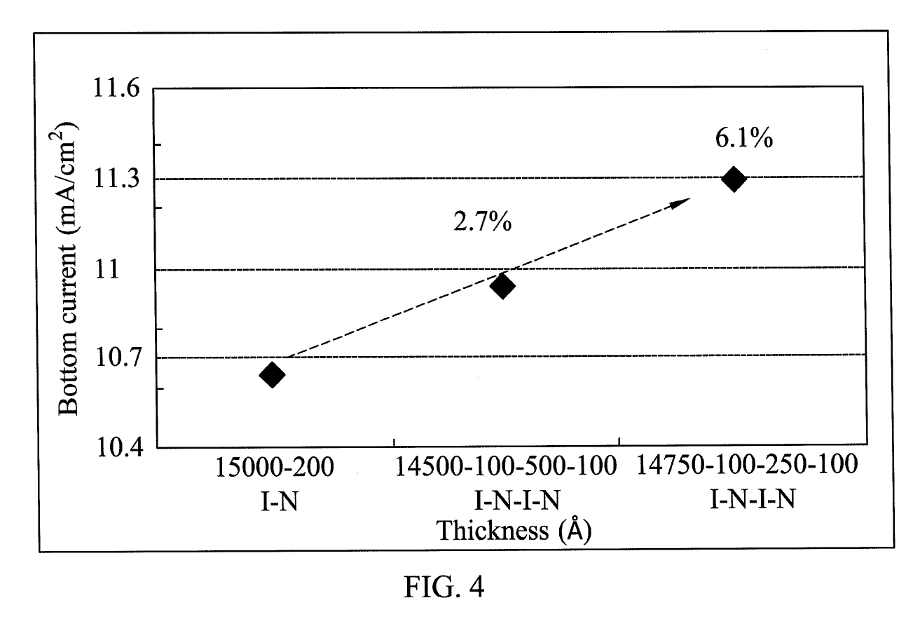

FIG. 4 is a data map comparing the variation of bottom currents of thin-film solar cells of prior art and the present invention and comparing the variation of bottom currents of the three-layered P-I-N semiconductor layer 12 of prior art (FIG. 1) and the PININ crystalline silicon layer (semiconductor layer) of the present invention. Referring to FIG. 4, when the second I-type crystalline silicon layer 250 of the thin-film solar cell 2 of the present invention has a thickness of 250 Å, the variation of bottom currents can rise 6.1%. It can prove that the thin-film solar cell 2 of the present invention can increase the currents and enhance photoelectric conversion efficiency.

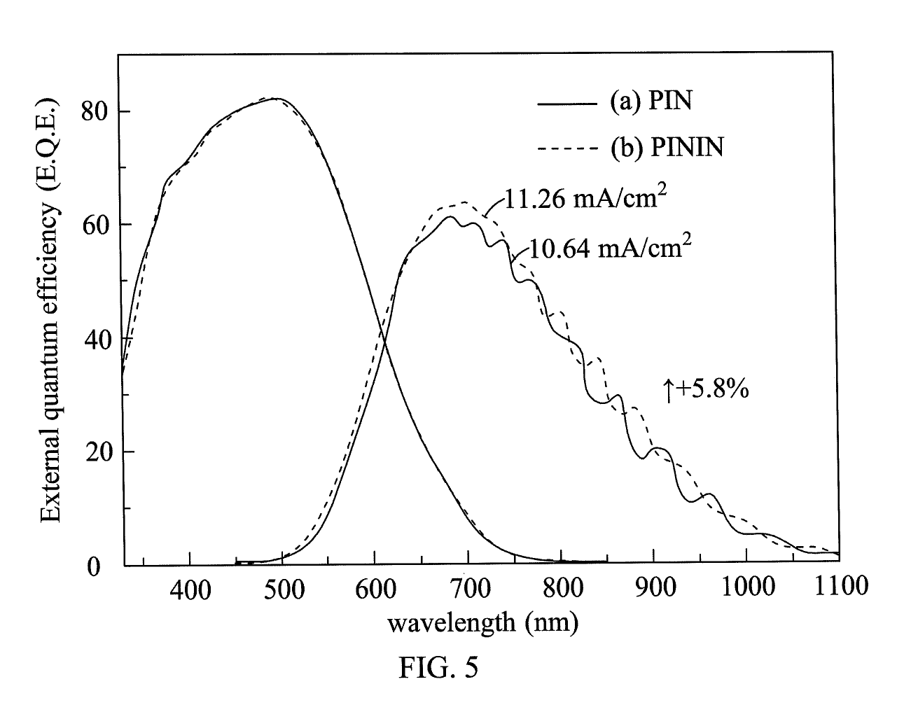

FIG. 5 is a curve diagram comparing the external quantum efficiencies (E.Q.E.) of thin-film solar cells of prior art and the present invention. Referring to FIG. 5, the thin-film solar cell 1 of prior art has a bottom current of 10.64 mA/cm², but without changing the thickness of semiconductor layer 12, the thin-film solar cell 2 of the present invention when having the same thickness as that of the semiconductor layer 12 of the thin-film solar cell of prior art has a bottom current of 11.26 mA/cm² and the variation of bottom currents rising 5.8%. It can further prove that the thin-film solar cell 2 of the present invention can increase the currents and enhance photoelectric conversion efficiency.

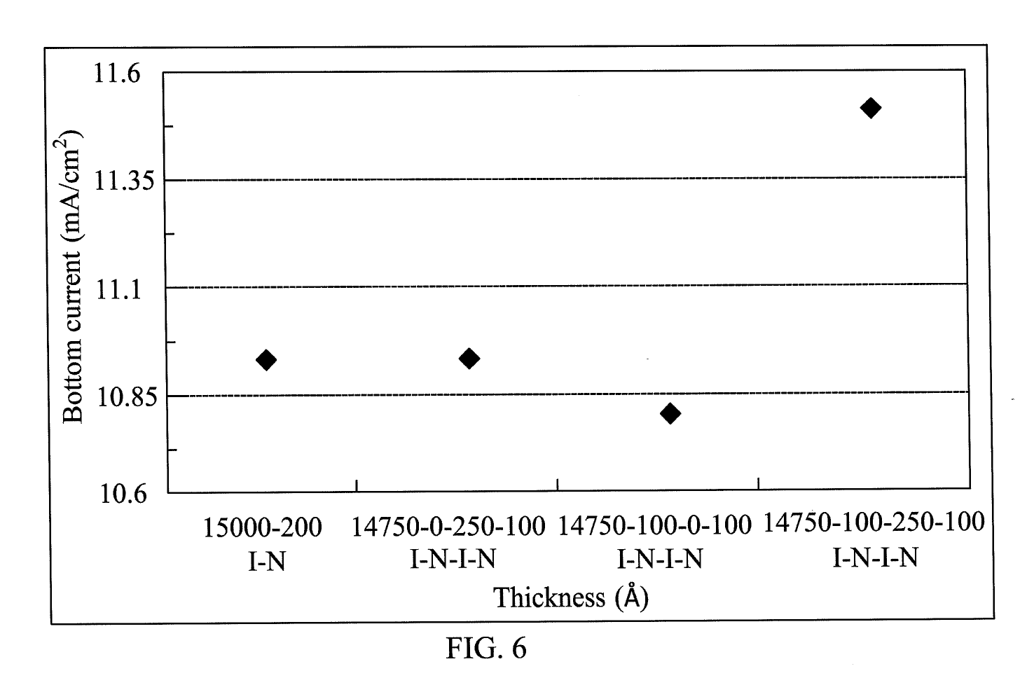

FIG. 6 is a data map comparing the variation of bottom currents of thin-film solar cells of the present invention, prior art and various compositions of semiconductor layers. In comparison between PIIN, PINN and PININ structures of the structural changes in the semiconductor layer 12 and the PIN structure of prior art, only the PININ crystalline silicon layer of the thin-film solar cell 2 of the present invention can enhance the photoelectric conversion efficiency of the thin-film solar cell 2.

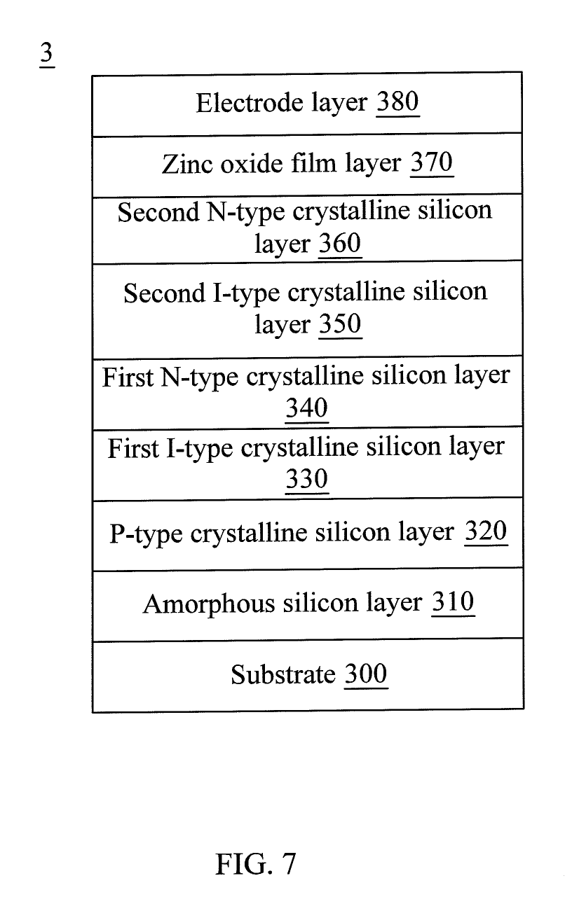

FIG. 7 is a schematic view of a thin-film solar cell in accordance with the second embodiment of the present invention. This embodiment is a structural change of the first embodiment. Referring to FIG. 7, a thin-film solar cell 3 may include a substrate 300, an amorphous silicon layer 310 on the substrate 300, a P-type crystalline silicon layer 320 on the amorphous silicon layer 310, a first I-type crystalline silicon layer 330 on the P-type crystalline silicon layer 320, a first N-type crystalline silicon layer 340 on the first I-type crystalline silicon layer 330, a second I-type crystalline silicon layer 350 on the first N-type crystalline silicon layer 340, a second N-type crystalline silicon layer 360 on the second I-type crystalline silicon layer 350, a zinc oxide film layer 370 on the second N-type crystalline silicon layer 360 and an electrode layer 380 on the zinc oxide film layer 370. The structural difference between this embodiment and the first embodiment is that the thickness of the first I-type crystalline silicon layer 330 can be less than or equal to 20% of a thickness of the second I-type crystalline silicon layer 350. Preferably, the total thickness of the first and second N-type crystalline silicon layers 340 and 360 is less than or equal to 10% of the thickness of the second I-type crystalline silicon layer 350 or less than or equal to 200 Å.

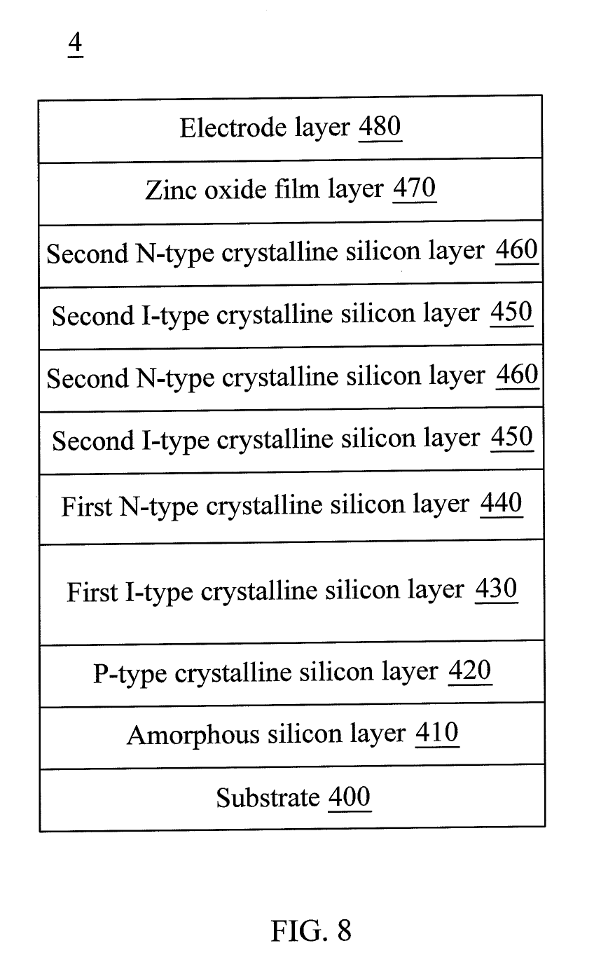

FIG. 8 is a schematic view of a thin-film solar cell in accordance with the third embodiment of the present invention. This embodiment is another structural change of the first embodiment. Referring to FIG. 8, a thin-film solar cell 4 may include a substrate 400, an amorphous silicon layer 410 on the substrate 400, a P-type crystalline silicon layer 420 on the amorphous silicon layer 410, a first I-type crystalline silicon layer 430 on the P-type crystalline silicon layer 420, a first N-type crystalline silicon layer 440 on the first I-type crystalline silicon layer 430, a plurality of second I-type crystalline silicon layers 450 having a bottommost one on the first N-type crystalline silicon layer 440, a plurality of second N-type crystalline silicon layers 460 interdigitally arranged with the second I-type crystalline silicon layers 450, a zinc oxide film layer 470 on the topmost one of the second N-type crystalline silicon layers 460 and an electrode layer 480 on the zinc oxide film layer 470. Preferably, the total thickness of the second I-type crystalline silicon layers 450 can be less than or equal to 20% of a thickness of the first I-type crystalline silicon layer 430. Preferably, the total thickness of the first N-type crystalline silicon layer 440 and the second N-type crystalline silicon layers 460 can be less than or equal to 10% of the thickness of the first I-type crystalline silicon layer 430 or less than or equal to 200 Å. In this embodiment, the number of the additional second I-type crystalline silicon layers 450 and second N-type crystalline silicon layers 460 in the semiconductor layer of the thin-film solar cell 4 is not limited, but a total thickness of the first I-type crystalline silicon layer 430 and the additional second I-type crystalline silicon layers 450 can be equal to that of the I-type crystalline silicon layer 122 of the thin-film solar cell 1 of prior art, and the total thickness of the first N-type crystalline silicon layer 440 and the additional second N-type crystalline silicon layers 460 can be equal to that of the N-type crystalline silicon layer 123 of the thin-film solar cell 1 of prior art.

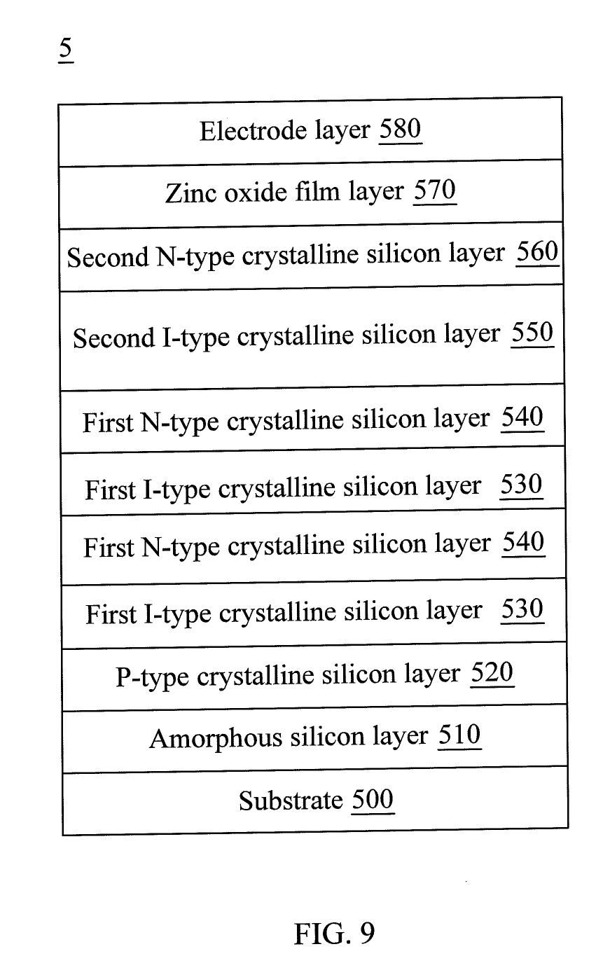

FIG. 9 is a schematic view of a thin-film solar cell in accordance with the fourth embodiment of the present invention. This embodiment is another structural change of the first embodiment. Referring to FIG. 9, a thin-film solar cell 5 may include a substrate 500, an amorphous silicon layer 510 on the substrate 500, a P-type crystalline silicon layer 520 on the amorphous silicon layer 510, a plurality of first I-type crystalline silicon layers 530 having a bottommost one on the P-type crystalline silicon layer 520, a plurality of first N-type crystalline silicon layers 540 interdigitally arranged with the first I-type crystalline silicon layers 530, a second I-type crystalline silicon layer 550 on the topmost one of the first N-type crystalline silicon layers 540, a second N-type crystalline silicon layer 560 on the second I-type crystalline silicon layer 550, a zinc oxide film layer 570 on the second N-type crystalline silicon layer 560 and an electrode layer 580 on the zinc oxide film layer 570. Preferably, the total thickness of the first I-type crystalline silicon layers 530 can be less than or equal to 20% of the thickness of the second I-type crystalline silicon layer 550. Preferably, the total thickness of the first N-type crystalline silicon layers 540 and the second N-type crystalline silicon layer 560 can be less than or equal to 10% of the thickness of the second I-type crystalline silicon layer 550 or less than or equal to 200 Å.

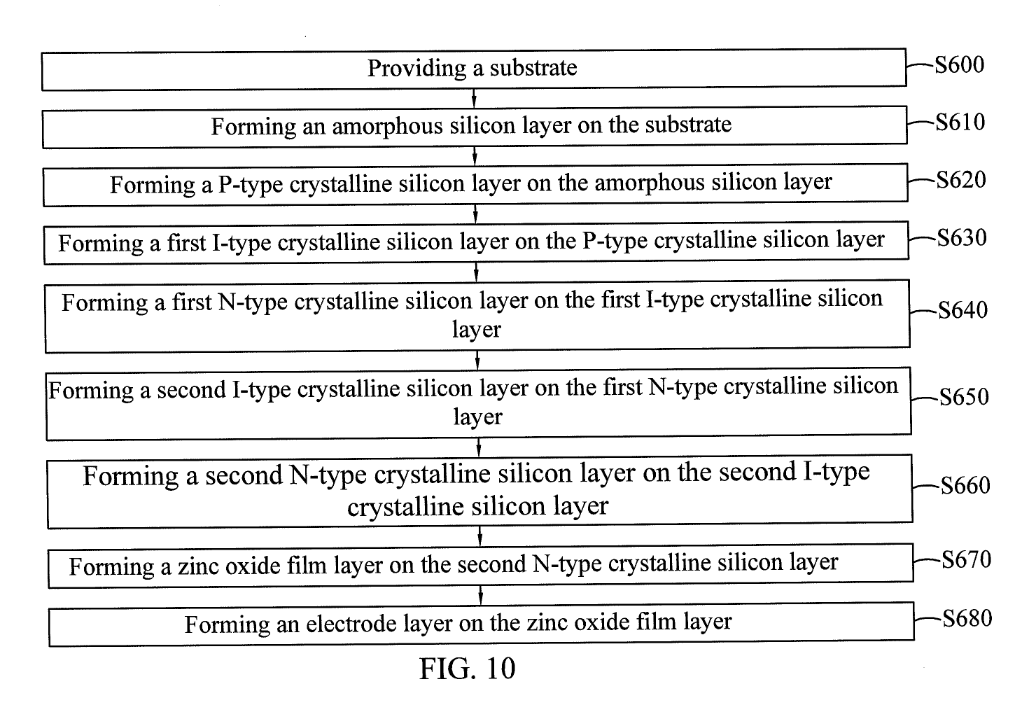

FIG. 10 is a flow chart for forming a thin-film solar cell in accordance with an embodiment of the present invention. Referring to FIG. 10, a method for forming a thin-film solar cell includes a step S600 of providing a substrate that can be made of glass or other transparent materials. Next, a step S610 is performed to form an amorphous silicon layer on the substrate, which acts as a light absorption layer. Next, a step S620 is performed to form a P-type crystalline silicon layer on the amorphous silicon layer. Next, a step S630 is performed to form a first I-type crystalline silicon layer on the P-type crystalline silicon layer. Next, a step S640 is performed to form a first N-type crystalline silicon layer on the first I-type crystalline silicon layer. Next, a step S650 is performed to form a second I-type crystalline silicon layer on the first N-type crystalline silicon layer. Next, a step S660 is performed to form a second N-type crystalline silicon layer on the second I-type crystalline silicon layer. Next, a step S670 is performed to form a zinc oxide film layer on the second N-type crystalline silicon layer. Next, a step S680 is performed to form an electrode layer on the zinc oxide film layer. The second I-type crystalline silicon layer may have a thickness less than or equal to 20% of a thickness of the first I-type crystalline silicon layer, or the first I-type crystalline silicon layer may have the thickness less than or equal to 20% of the thickness of the second I-type crystalline silicon layer. The total thickness of the first and second N-type crystalline silicon layers can be less than or equal to 10% of the thickness of the first or second I-type crystalline silicon layer or less than or equal to 200 Å. In this embodiment, the first I-type crystalline silicon layer and the first N-type crystalline silicon layer, or the second I-type crystalline silicon layer and the second N-type crystalline silicon layer can be composed of multiple layers, but the total thickness thereof is not changed.

In summary, the thin-film solar cell and the method for forming the same of the present invention is a structural modification of the three-layered P-I-N semiconductor layer of prior art by adding additional I-type and N-type crystalline silicon layers, and thereby enhancing photoelectric conversion efficiency.

While the means of specific embodiments in present invention has been described by reference drawings, numerous modifications and variations could be made thereto by those skilled in the art without departing from the scope and spirit of the invention set forth in the claims. The modifications and variations should in a range limited by the specification of the present invention.

What is claimed is:

1. A thin-film solar cell comprising:
a substrate; and
a semiconductor layer comprising a P-type crystalline silicon layer over the substrate, a first I-type crystalline silicon layer on the P-type crystalline silicon layer, a first N-type crystalline silicon layer on the first I-type crystalline silicon layer, a second I-type crystalline silicon layer on the first N-type crystalline silicon layer and a second N-type crystalline silicon layer on the second I-type crystalline silicon layer, wherein the second I-type crystalline silicon layer has a thickness less than or equal to 20% of a thickness of the first I-type crystalline silicon layer.

2. The thin-film solar cell of claim 1, wherein the substrate comprises a glass.

3. The thin-film solar cell of claim 1 further comprising an amorphous silicon layer between the substrate and the P-type crystalline silicon layer.

4. The thin-film solar cell of claim 1 further comprising a zinc oxide film layer on the second N-type crystalline silicon layer.

5. The thin-film solar cell of claim 4 further comprising an electrode layer on the zinc oxide film layer.

6. The thin-film solar cell of claim 5, wherein the electrode layer is made of a conductive metal.

7. The thin-film solar cell of claim 1, wherein the first and second I-type crystalline silicon layers and the first and second N-type crystalline silicon layers comprise an amorphous silicon and a micro-crystalline silicon.

8. The thin-film solar cell of claim 1, wherein a total thickness of the first and second N-type crystalline silicon layers is less than or equal to 10% of the thickness of the first I-type crystalline silicon layer.

9. The thin-film solar cell of claim 1, wherein a total thickness of the first and second N-type crystalline silicon layers is less than or equal to 200 Å.

10. A thin-film solar cell comprising:
a substrate; and
a semiconductor layer comprising a P-type crystalline silicon layer over the substrate, a first I-type crystalline silicon layer on the P-type crystalline silicon layer, a first N-type crystalline silicon layer on the first I-type crystalline silicon layer, a second I-type crystalline silicon layer on the first N-type crystalline silicon layer and a second N-type crystalline silicon layer on the second I-type crystalline silicon layer, wherein the first I-type crystalline silicon layer has a thickness less than or equal to 20% of a thickness of the second I-type crystalline silicon layer.

11. The thin-film solar cell of claim 10, wherein the substrate comprises a glass.

12. The thin-film solar cell of claim 10 further comprising an amorphous silicon layer between the substrate and the P-type crystalline silicon layer.

13. The thin-film solar cell of claim 10 further comprising a zinc oxide film layer on the second N-type crystalline silicon layer.

14. The thin-film solar cell of claim 13 further comprising an electrode layer on the zinc oxide film layer.

15. The thin-film solar cell of claim 14, wherein the electrode layer is made of a conductive metal.

16. The thin-film solar cell of claim 10, wherein the first and second I-type crystalline silicon layers and the first and second N-type crystalline silicon layers comprise an amorphous silicon and a micro-crystalline silicon.

17. The thin-film solar cell of claim 10, wherein a total thickness of the first and second N-type crystalline silicon layers is less than or equal to 10% of the thickness of the second I-type crystalline silicon layer.

18. The thin-film solar cell of claim 10, wherein a total thickness of the first and second N-type crystalline silicon layers is less than or equal to 200 Å.

19. A method for forming a thin-film solar cell, comprising:
providing a substrate;
forming a P-type crystalline silicon layer over the substrate;
forming a first I-type crystalline silicon layer on the P-type crystalline silicon layer;
forming a first N-type crystalline silicon layer on the first I-type crystalline silicon layer;
forming a second I-type crystalline silicon layer on the first N-type crystalline silicon layer; and
forming a second N-type crystalline silicon layer on the second I-type crystalline silicon layer.

20. The method of claim 19, wherein the second I-type crystalline silicon layer has a thickness less than or equal to 20% of a thickness of the first I-type crystalline silicon layer.

21. The method of claim 19, wherein the first I-type crystalline silicon layer has a thickness less than or equal to 20% of a thickness of the second I-type crystalline silicon layer.

22. The method of claim 19, wherein the substrate comprises a glass.

23. The method of claim 19 further comprising forming an amorphous silicon layer between the substrate and the P-type crystalline silicon layer.

24. The method of claim 19 further comprising forming a zinc oxide film layer on the second N-type crystalline silicon layer.

25. The method of claim 24 further comprising forming an electrode layer on the zinc oxide film layer.

26. The method of claim 25, wherein the electrode layer is made of a conductive metal.

27. The method of claim 19, wherein the first and second I-type crystalline silicon layers and the first and second N-type crystalline silicon layers comprise an amorphous silicon and a micro-crystalline silicon.

28. The method of claim 19, wherein a total thickness of the first and second N-type crystalline silicon layers is less than or equal to 10% of a thickness of the first I-type crystalline silicon layer.

29. The method of claim 19, wherein a total thickness of the first and second N-type crystalline silicon layers is less than or equal to 10% of a thickness of the second I-type crystalline silicon layer.

30. The method of claim 19, wherein a total thickness of the first and second N-type crystalline silicon layers is less than or equal to 200 Å.

31. A thin-film solar cell comprising:
a substrate; and
a semiconductor layer containing a P-type crystalline silicon layer over the substrate, a first I-type crystalline silicon layer on the P-type crystalline silicon layer, a first N-type crystalline silicon layer on the first I-type crystalline silicon layer, a plurality of second I-type crystalline silicon layers having a bottommost one on the first N-type crystalline silicon layer, and a plurality of second N-type crystalline silicon layers interdigitally arranged with the second I-type crystalline silicon layers, wherein a total thickness of the second I-type crystalline silicon layers is less than or equal to 20% of a thickness of the first I-type crystalline silicon layer.

32. The thin-film solar cell of claim 31, wherein the substrate comprises a glass.

33. The thin-film solar cell of claim 31 further comprising an amorphous silicon layer between the substrate and the P-type crystalline silicon layer.

34. The thin-film solar cell of claim 31 further comprising a zinc oxide film layer on the topmost one of the second N-type crystalline silicon layers interdigitally arranged.

35. The thin-film solar cell of claim 34 further comprising an electrode layer on the zinc oxide film layer.

36. The thin-film solar cell of claim 35, wherein the electrode layer is made of a conductive metal.

37. The thin-film solar cell of claim 31, wherein the first and second I-type crystalline silicon layers and the first and second N-type crystalline silicon layers comprise an amorphous silicon and a micro-crystalline silicon.

38. The thin-film solar cell of claim 31, wherein a total thickness of the first and second N-type crystalline silicon layers is less than or equal to 10% of the thickness of the first I-type crystalline silicon layer.

39. The thin-film solar cell of claim 31, wherein a total thickness of the first and second N-type crystalline silicon layers is less than or equal to 200 Å.

40. A thin-film solar cell comprising:
a substrate; and
a semiconductor layer containing a P-type crystalline silicon layer over the substrate, a plurality of first I-type crystalline silicon layers having a bottommost one on the P-type crystalline silicon layer, a plurality of first N-type crystalline silicon layers interdigitally arranged with the first I-type crystalline silicon layers, a second I-type crystalline silicon layer on the topmost one of the first N-type crystalline silicon layers, and a second N-type crystalline silicon layer on the second I-type crystalline silicon layer, wherein a total thickness of the first I-type crystalline silicon layers is less than or equal to 20% of a thickness of the second I-type crystalline silicon layer.

41. The thin-film solar cell of claim 40, wherein the substrate comprises a glass.

42. The thin-film solar cell of claim 40 further comprising an amorphous silicon layer between the substrate and the P-type crystalline silicon layer.

43. The thin-film solar cell of claim 40 further comprising a zinc oxide film layer on the second N-type crystalline silicon layer.

44. The thin-film solar cell of claim 43 further comprising an electrode layer on the zinc oxide film layer.

45. The thin-film solar cell of claim 44, wherein the electrode layer is made of a conductive metal.

46. The thin-film solar cell of claim 40, wherein the first and second I-type crystalline silicon layers and the first and second N-type crystalline silicon layers comprise an amorphous silicon and a micro-crystalline silicon.

47. The thin-film solar cell of claim 40, wherein a total thickness of the first and second N-type crystalline silicon layers is less than or equal to 10% of the thickness of the second I-type crystalline silicon layer.

48. The thin-film solar cell of claim 40, wherein a total thickness of the first and second N-type crystalline silicon layers is less than or equal to 200 Å.
